(19) United States
(12) Patent Application Publication
(10) Pub. No.: US 2023/0014288 A1
(43) Pub. Date: Jan. 19, 2023

(54) STAGGERING SIGNAL GENERATION CIRCUIT AND INTEGRATED CHIP

(71) Applicant: CHANGXIN MEMORY TECHNOLOGIES, INC., Hefei City (CN)

(72) Inventor: Yuanyuan SUN, Hefei City (CN)

(73) Assignee: CHANGXIN MEMORY TECHNOLOGIES, INC., Hefei City (CN)

(21) Appl. No.: 17/648,806

(22) Filed: Jan. 24, 2022

Related U.S. Application Data
(63) Continuation of application No. PCT/CN2021/108767, filed on Jul. 27, 2021.

(30) Foreign Application Priority Data
Jul. 16, 2021 (CN) 202110805988.9

(51) Int. Cl. H03K 5/151; G06F 1/06; H03K 5/12

(52) U.S. Cl. CPC H03K 5/1515; G06F 1/06; H03K 5/12

(57) ABSTRACT

A staggering signal generation circuit includes a pulse generation circuit, a counting circuit and a signal generation circuit. The pulse generation circuit generates a first periodic pulse signal and a second periodic pulse signal; the counting circuit counts the first periodic pulse signal and the second periodic pulse signal to generate rising edge triggering signals and falling edge triggering signals; and the signal generation circuit generate a staggering pulse signal according to the input rising edge triggering signals and the input falling edge triggering signals.

### CROSS-REFERENCE TO RELATED APPLICATIONS

This is a continuation of International Patent Application No. PCT/CN2021/108767 filed on Jul. 27, 2021, which claims priority to Chinese Patent Application No. 202110805988.9 filed on Jul. 16, 2021. The disclosures of the above-referenced applications are hereby incorporated by reference in their entirety.

### BACKGROUND

At present, technical indexes, such as high integration level, functional diversity, low power consumption, and miniaturization, are increasingly emphasized in the field of chip designs. As various technologies in chip industry innovate continuously, and the requirements on simplification of a system application design and the diversification of design functions emerge, the design of chip circuits becomes more complex. Therefore, the requirements for the flexibility and functional diversity of signal generation circuits are increasingly improved.

### SUMMARY

The disclosure relates to the technical field of circuits, and in particular, to a staggering signal generation circuit and an integrated chip.

The disclosure provides a staggering signal generation circuit and an integrated chip, so as to solve the problem that the staggering signal generation circuit in the existing technology is not flexible enough.

According to a first aspect, embodiments of the disclosure provide a staggering signal generation circuit, which includes a pulse generation circuit, a counting circuit, and a signal generation circuit.

The pulse generation circuit is configured to generate a first periodic pulse signal and a second periodic pulse signal according to a delay signal and an initial signal.

The counting circuit is configured to count the first periodic pulse signal and the second periodic pulse signal to generate rising edge triggering signals and falling edge triggering signals.

The signal generation circuit is configured to generate a staggering pulse signal according to the input rising edge triggering signals and the input falling edge triggering signals.

In one possible implementation manner, the signal generation circuit may include a plurality of signal generation sub-circuits.

Each signal generation sub-circuit is configured to generate a staggering pulse sub-signal according to the input rising edge triggering signals and the input falling edge triggering signals.

A plurality of the staggering pulse sub-signals forms a staggering pulse signal.

In one possible implementation manner, the signal generation sub-circuit may include a Set-Reset (SR) latch, a first NOT gate, and a second NOT gate.

A first input terminal of the SR latch is configured to input the rising edge triggering signal. A second input terminal of the SR latch is configured to input the falling edge triggering signal. A third input terminal of the SR latch is configured to input a rising edge staggering enabling signal. An output terminal of the SR latch is connected to an input terminal of the first NOT gate.

An output terminal of the first NOT gate is connected to an input terminal of the second NOT gate.

An output terminal of the second NOT gate is configured to output the staggering pulse sub-signal.

In one possible implementation manner, if the time intervals of rising edge counting signals input into adjacent signal generation sub-circuits of the plurality of signal generation sub-circuits are the same, the staggering pulse signal is a staggering pulse signal with equal interval.

If the time intervals of the rising edge counting signals input into the adjacent signal generation sub-circuits of the plurality of signal generation sub-circuits are different, the staggering pulse signal is a staggering pulse signal with unequal interval.

If the time intervals of the rising edge counting signals and the corresponding falling edge counting signals input into each of the signal generation sub-circuits are the same, the staggering pulse signal is a staggering pulse signal with equal pulse width.

If the time intervals of the rising edge counting signals and the corresponding falling edge counting signals input into each of the signal generation sub-circuits are different, the staggering pulse signal is a staggering pulse signal with unequal pulse width.

In one possible implementation manner, the pulse generation circuit may include a first periodic pulse signal generation circuit and a second periodic pulse signal generation circuit.

The first periodic pulse signal generation circuit is configured to generate the first periodic pulse signal according to the delay signal, the initial signal, the rising edge staggering enabling signal, a rising edge staggering adjustment delay signal, and a rising edge staggering adjustment delay inverted signal.

The second periodic pulse signal generation circuit is configured to generate the second periodic pulse signal according to the delay signal, the initial signal, a falling edge staggering enabling signal, a rising edge staggering adjustment delay signal, and a rising edge staggering adjustment delay inverted signal.

In one possible implementation manner, the first periodic pulse signal generation circuit may include a first oscillator and a third NOT gate.

A first input terminal of the first oscillator is configured to input the initial signal. A second input terminal of the first oscillator is configured to input the rising edge staggering enabling signal. A third input terminal of the first oscillator is configured to input the rising edge staggering adjustment delay signal. A fourth input terminal of the first oscillator is configured to input the rising edge staggering adjustment delay inverted signal. An output terminal of the first oscillator is connected with an input terminal of the third NOT gate and is configured to output a rising edge clock signal. An output terminal of the third NOT gate is configured to output the first periodic pulse signal.

The falling edge clock signal generation circuit includes a second oscillator, a fourth NOT gate, and a first NAND gate.

An input terminal of the fourth NOT gate is configured to input the initial signal. An output terminal of the fourth NOT gate is connected to a first input terminal of the second oscillator.

A second input terminal of the second oscillator is configured to input the falling edge staggering enabling signal. A third input terminal of the second oscillator is configured to input the rising edge staggering adjustment delay signal. A fourth input terminal of the second oscillator is configured to input the rising edge staggering adjustment delay inverted signal. An output terminal of the second oscillator is connected to a first input terminal of the first NAND gate and is configured to output a falling edge clock signal.

A second input terminal of the first NAND gate is configured to input the falling edge enabling signal, and an output terminal of the first NAND gate is configured to output the second periodic pulse signal.

In one possible implementation manner, the staggering signal generation circuit further includes a fifth NOT gate and a flip-flop.

An input terminal of the fifth NOT gate is connected to a terminal Clk of the flip-flop and is configured to input ActEnPlaN. An output terminal of the fifth NOT gate is connected to an inverted clock terminal ClkN of the flip-flop.

A terminal D of the flip-flop is grounded. A terminal RN of the flip-flop is configured to input the rising edge staggering enabling signal. A terminal Q of the flip-flop is configured to output the falling edge enabling signal.

In one possible implementation manner, the signal generation sub-circuit further includes a second NAND gate, a third NAND gate, a fourth NAND gate, a sixth NOT gate, a seventh NOT gate, an eighth NOT gate, a ninth NOT gate, a tenth NOT gate, and a pulse conversion unit are further included.

A first input terminal of the second NAND gate is configured to input FnCoreActAllBnk. A second input terminal of the second NAND gate is configured to input Burnin. An output terminal of the second NAND gate is connected to an input terminal of the sixth NOT gate.

An output terminal of the sixth NOT gate is configured to output a rising edge staggering enabling signal.

A first input terminal of the third NAND gate is configured to input RosEnBnki. A second input terminal of the third NAND gate is configured to input the rising edge staggering enabling signal. An output terminal of the third NAND gate is connected to an input terminal of the seventh NAND gate.

An output terminal of the seventh gate is connected to an input terminal of the pulse conversion unit and is configured to output the initial signal.

An output terminal of the pulse conversion unit is connected to a first input terminal of the fourth NAND gate.

A second input terminal of the fourth NAND gate is configured to input the rising edge staggering enabling signal. An output terminal of the fourth NAND gate is connected to an input terminal of the eighth NAND gate.

An output terminal of the eighth NOT gate is configured to output the falling edge staggering enabling signal.

An input terminal of the ninth NOT gate is configured to input ActStaggerDly. An output terminal of the ninth NOT gate is connected to an input terminal of the tenth NOT gate and is configured to output the rising edge staggering adjustment delay inverted signal.

An output terminal of the tenth NOT gate is configured to output the rising edge staggering adjustment delay signal.

In one possible implementation manner, the counting circuit includes a plurality of rising edge triggering signal generation circuits connected in series and a plurality of falling edge triggering signal generation circuits connected in series.

The rising edge triggering signal generation circuit is configured to generate the rising edge triggering signal according to the first periodic pulse signal, the rising edge staggering enabling delay signal, the rising edge staggering enabling signal, a power supply voltage VSS, and a rising edge counting signal output by a last rising edge counting signal generation circuit connected to the rising edge triggering signal generation circuit.

The falling edge triggering signal generation circuit is configured to generate the falling edge triggering signal according to the second periodic pulse signal, the falling edge staggering enabling delay signal, the falling edge staggering enabling signal, the VSS, and a falling edge counting signal output by a last falling edge counting signal generation circuit connected to the falling edge triggering signal generation circuit.

In one possible implementation manner, the rising edge triggering signal generation circuit includes a first counter and an eleventh NOT gate.

A first input terminal of the first counter is configured to input the first periodic pulse signal. A second input terminal of the first counter is configured to input the rising edge staggering enabling delay signal. A third input terminal of the first counter is configured to input the power supply voltage VSS or a rising edge counting signal output by a last first counter connected to the first counter. A fourth input terminal of the first counter is configured to input the rising edge staggering enabling signal. A fifth input terminal of the first counter is configured to input the VSS. An output terminal of the first counter is connected to a third input terminal of a next first counter and an input terminal of the eleventh NOT gate, and is configured to output the rising edge counting signal.

An output terminal of the eleventh NOT gate is configured to output the rising edge triggering signal.

The falling edge triggering signal generation circuit includes a second counter and a twelfth NOT gate.

A first input terminal of the second counter is configured to input the second periodic pulse signal. A second input terminal of the second counter is configured to input the falling edge staggering enabling delay signal. A third input terminal of the second counter is configured to input the VSS or a falling edge counting signal output by a last second counter connected to the second counter. A fourth input terminal of the second counter is configured to input a falling edge staggering enabling signal. A fifth input terminal of the second counter is configured to input the VSS. An output terminal of the second counter is connected to an input terminal of the twelfth NOT gate and is configured to output a falling edge counting signal.

An output terminal of the twelfth NOT gate is configured to output the falling edge triggering signal.

In one possible implementation manner, a first delayer, a second delayer, a third delayer, a fourth delayer, a fifth delayer, a sixth delayer, a seventh delayer, an eighth delayer, an NOR gate, and a thirteenth NOT gate are further included.

An input terminal of the first delayer is configured to input the initial signal. An output terminal of the first delayer is connected to an input terminal of the second delayer. An output terminal of the second delayer is connected to an input terminal of the third delayer. An output terminal of the third delayer is connected to an input terminal of the fourth delayer. An output terminal of the fourth delayer is configured to output the rising edge staggering enabling delay signal.

A first input terminal of the NOR gate is configured to input the initial signal. A second input terminal of the NOR gate is configured to input the falling edge enabling signal. An output terminal of the NOR gate is connected to an input terminal of the thirteenth NOT gate. An output terminal of the thirteenth NOT gate is connected to an input terminal of the fifth delayer. An output terminal of the fifth delayer is connected to an input terminal of the sixth delayer. An output terminal of the sixth delayer is connected to an input terminal of the seventh delayer. An output terminal of the seventh delayer is connected to an input terminal of the eighth delayer. An output terminal of the eighth delayer is configured to output the falling edge staggering enabling delay signal.

According to a second aspect, the embodiments of the disclosure provide an integrated chip, which includes the staggering signal generation circuit according to any one of the first aspect as described above.

### BRIEF DESCRIPTION OF THE DRAWINGS

In order to describe the technical solutions in the embodiments of the disclosure more clearly, the following briefly describes the accompanying drawings required for describing the embodiments. It is apparent that the accompanying drawings in the following description show merely some embodiments of the disclosure, and a person of ordinary skill in the art may derive other drawings from these accompanying drawings without creative efforts.

FIG. 1 is a schematic structural diagram of a staggering signal generation circuit provided by embodiments of the disclosure.

FIG. 2 is a schematic structural diagram of a first periodic pulse signal generation circuit provided by the embodiments of the disclosure.

FIG. 3 is a schematic structural diagram of a second periodic pulse signal generation circuit provided by the embodiments of the disclosure.

FIG. 4 is a schematic structural diagram of an oscillator provided by the embodiments of the disclosure.

FIG. 5 is a schematic structural diagram of another staggering signal generation circuit provided by the embodiments of the disclosure.

FIG. 6 is a schematic structural diagram of a rising edge staggering enabling signal generation circuit provided by the embodiments of the disclosure.

FIG. 7 is a schematic structural diagram of a falling edge staggering enabling signal generation circuit provided by the embodiments of the disclosure.

FIG. 8 is a generation circuit of rising edge staggering adjustment delay signal and rising edge staggering adjustment delay inverted signal provided by the embodiments of the disclosure.

FIG. 9 is a waveform diagram of a signal provided by the embodiments of the disclosure.

FIG. 10 is a schematic structural diagram of a rising edge triggering signal generation circuit provided by the embodiments of the disclosure.

FIG. 11 is another schematic structural diagram of a rising edge triggering signal generation circuit provided by the embodiments of the disclosure.

FIG. 12 is a schematic structural diagram of a counter provided by the embodiments of the disclosure.

FIG. 13 is a schematic structural diagram of a rising edge staggering enabling delay signal generation circuit provided by the embodiments of the disclosure.

FIG. 14 is a schematic structural diagram of a falling edge staggering enabling delay signal generation circuit provided by the embodiments of the disclosure.

FIG. 15 is a schematic structural diagram of a signal generation sub-circuit provided by the embodiments of the disclosure.

FIG. 16 is a schematic structural diagram of another signal generation sub-circuit provided by the embodiments of the disclosure.

FIG. 17 is a waveform diagram of a staggering signal provided by the embodiments of the disclosure.

FIG. 18 is a schematic structural diagram of another signal generation sub-circuit provided by the embodiments of the disclosure.

FIG. 19 is a waveform diagram of another staggering signal provided by the embodiments of the disclosure.

FIG. 20 is a schematic structural diagram of another signal generation sub-circuit provided by the embodiments of the disclosure.

FIG. 21 is a waveform diagram of another staggering signal provided by the embodiments of the disclosure.

FIG. 22 is a schematic structural diagram of another signal generation sub-circuit provided by the embodiments of the disclosure.

FIG. 23 is a waveform diagram of another staggering signal provided by the embodiments of the disclosure.

### DETAILED DESCRIPTION

To make the objectives, technical solutions, and advantages of the disclosure clearer, the following further describes the disclosure in detail with reference to the accompanying drawings. It is apparent that the described embodiments are merely some rather than all of the embodiments of the disclosure. All other embodiments obtained by a person of ordinary skill in the art based on the embodiments of the disclosure without creative efforts shall fall within the protection scope of the disclosure.

Staggering signals are commonly used in the field of chip circuit designs. The staggering signals may include staggering signals with equal interval and equal pulse width, staggering signals with unequal interval and equal pulse width, staggering signals with equal interval and unequal pulse width, and staggering signals with unequal interval and unequal pulse width.

In some implementations, a circuit for generating a staggering signal can generate only one type of staggering signals, which is not flexible enough.

The embodiments of the disclosure provide a staggering signal generation circuit and an integrated chip, so as to solve the problem of poor flexibility of the staggering signal generation circuit in the related art.

The staggering signal generation circuit and the integrated chip are based on the same inventive concept, and since the principles for solving technical problems by the staggering signal generation circuit and the integrated chip are similar, reference may be made each other to implementations of the staggering signal generation circuit and the integrated chip, and repeated description is omitted.

In the following specific introduction of the embodiments, it is to be noted that a plurality involved in the disclosure refers to two or more. The term “or” involved in the application describes an association relationship for describing associated objects and represents that three relationships may exist. For example, A or B may represent the following three cases: only A exists, both A and B exist, and only B exists. The connection involved in the disclosure describes the connection relationship of two objects, and may represent two connection relationships, for example, the connection of A and B may represent the following two cases: A is directly connected to B, and A is connected to B through C. In addition, it is to be understood that terms “first”, “second”, “third”, . . . , in the description of the disclosure are only used for distinguishing descriptions, and cannot be understood as indicating or implying relative importance, or understood as indicating or implying sequence.

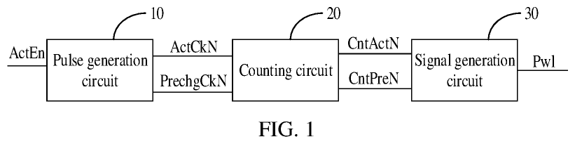

FIG. 1 is a schematic structural diagram of a staggering signal generation circuit provided by embodiments of the disclosure. The staggering signal generation circuit provided includes a pulse generation circuit 10, a counting circuit 20, and a signal generation circuit 30.

The pulse generation circuit 10 is configured to generate a first periodic pulse signal ActCkN and a second periodic pulse signal PrechgCkN according to an initial signal ActEn.

The counting circuit 20 is configured to count the first periodic pulse signal ActCkN and the second periodic pulse signal PrechgCkN to generate a rising edge triggering signal CntActN and a falling edge triggering signal CntPreN.

The signal generation circuit 30 is configured to generate staggering pulse signal Pwl according to the input rising edge triggering signal CntActN and the input falling edge triggering signal CntPrechgN.

In the embodiments of the disclosure, the counting circuit counts the first periodic pulse signals and the second periodic pulse signals to generate the rising edge triggering signal and the falling edge triggering signal, and the signal generation circuit generates the staggering pulse signal according to the input rising edge triggering signal and the input falling edge triggering signal. The intervals between the rising edge triggering signals input into each signal generation circuit may be the same or different, and the intervals between the rising edge triggering signal and the falling edge triggering signal input into each signal generation circuit may also be the same or different, and thus the pulse width and the interval of the obtained staggering pulse signals may be set flexibly, thereby improving the flexibility of the staggering pulse signal generation circuit.

In a specific implementation, the pulse generation circuit 10 may include a first periodic pulse signal generation circuit and a second periodic pulse signal generation circuit.

The first periodic pulse signal generation circuit is configured to generate the first periodic pulse signal ActCkN according to the initial signal ActEn and a first control signal.

The second periodic pulse signal generation circuit is configured to generate the second periodic pulse signal PrechgCkA according to the initial signal ActEn and a second control signal.

The first control signal may include rising edge staggering enabling signal FnstaggerActEn, rising edge staggering adjustment delay signal FnAdjActStaggerDly, and rising edge staggering adjustment delay inverted signal FnAdjActStaggerDlyN. The second control signal may include falling edge staggering enabling signal FnstaggerPrecchgEn, rising edge staggering adjustment delay signal FnAdjActStaggerDly, rising edge staggering adjustment delay inverted signal FnAdjActStaggerDlyN, and falling edge enabling signal PreEn.

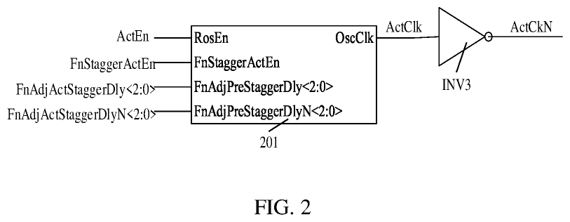

Specifically, FIG. 2 is a schematic structural diagram of a first periodic pulse signal generation circuit provided by the embodiments of the disclosure.

The first periodic pulse signal generation circuit may include a first oscillator 201 and a third NOT gate INV3.

A first input terminal of the first oscillator 201 is configured to input the initial signal ActEn. A second input terminal of the first oscillator 201 is configured to input the rising edge staggering enabling signal FnStaggerActEn. A third input terminal of the first oscillator 201 is configured to input the rising edge staggering adjustment delay signal FnAdjActStaggerDly. A fourth input terminal of the first oscillator 201 is configured to input the rising edge staggering adjustment delay inverted signal FnAdjActStaggerDlyN. An output terminal of the first oscillator 201 is connected to an input terminal of the third NOT gate INV3, and is configured to output the rising edge clock signal ActClk. An output terminal of the third NOT gate INV3 is configured to output the first periodic pulse signal ActCkN.

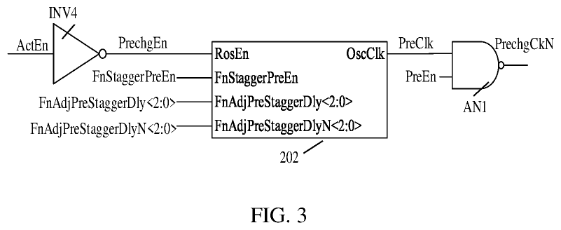

FIG. 3 is a schematic structural diagram of a second periodic pulse signal generation circuit provided by the embodiments of the disclosure.

The falling edge clock signal generation circuit may include a second oscillator 202, a fourth NOT gate INV4, and a first NAND gate AN1.

An input terminal of the fourth NOT gate INV4 is configured to input the initial signal ActEn. An output terminal of the fourth NOT gate INV4 is connected to a first input terminal of the second oscillator 202, and is configured to output the initial signal inverted signal PrechgEn.

A second input terminal of the second oscillator 202 is configured to input a falling edge staggering enabling signal FnStaggerPreEn. A third input terminal of the second oscillator 202 is configured to input the rising edge staggering adjustment delay signal FnAdjActStaggerDly. A fourth input terminal of the second oscillator 202 is configured to input the rising edge staggering adjustment delay inverted signal FnAdjActStaggerDlyN. An output terminal of the second oscillator 202 is connected to a first input terminal of the first NAND gate AN1 and is configured to output the falling edge clock signal PrechgClk.

A second input terminal the first NAND gate AN1 is configured to input a falling edge enabling signal PreEn. An output terminal of the first NAND gate AN1 is configured to output the second periodic pulse signal PrechgCkN.

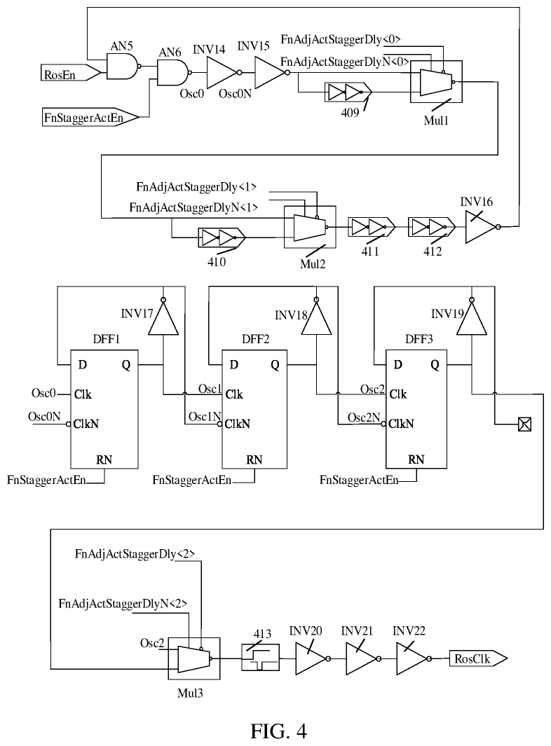

In the embodiments of the disclosure, specific structures of the first oscillator 201 and the second oscillator 202 may be the same. Specifically, reference may be made to the oscillator structure shown in FIG. 4.

FIG. 4 is a schematic structural diagram of an oscillator provided by the embodiments of the disclosure.

The oscillator may include a fifth NAND gate AN5, a sixth NAND gate AN6, a fourteenth NOT gate INV14, a fifteenth NOT gate INV15, a sixteenth NOT gate INV16, a seventeenth NOT gate INV17, an eighteenth NOT gate INV18, a nineteenth NOT gate INV19, a twentieth NOT gate INV20, a twenty-first NOT gate INV21, and a twenty-second NOT gate INV22, a first selector Mul1, a second selector Mul2, a third selector Mul3, a first flip-flop DFF1, a second flip-flop DFF2, a third flip-flop DFF3, a ninth delayer 409, a tenth delayer 410, an eleventh delayer 411, a twelfth delayer 412, and a first pulse conversion unit 413.

A first input terminal of the fifth NAND gate AN5 is connected to an output terminal of the sixteenth NAND gate INV16. A second input terminal of the fifth NAND gate AN5 serves as a first input terminal of the oscillator. An output terminal of the fifth NAND gate AN5 is connected to a first input terminal of the sixth NAND gate AN6 and is configured to output a delay signal Osc0. A second input terminal of the sixth NAND gate AN6, a terminal RN of the first flip-flop DFF1, a terminal RN of the second flip-flop DFF2, and a terminal RN of the third flip-flop DFF3 serve as a second input terminal of the oscillator. An output terminal of the sixth NAND gate AN6 is connected to an input terminal of the fourteenth NOT gate INV14. An output terminal of the fourteenth NOT gate INV14 is connected to an input terminal of the fifteenth NOT gate INV15 and is configured to output a delay inverted signal Osc0N. An output terminal of the fifteenth NOT gate INV15 is connected to a first input terminal of the first selector Mul1 and an input terminal of the ninth delayer 409. An output terminal of the ninth delayer 409 is connected to a second input terminal of the first selector Mul1. An output terminal of the first selector Mul1 is connected with a first input terminal of the second selector Mul2 and an input terminal of the tenth delayer 410. A first control terminal of the first selector Mul1 serves as a third input terminal of the oscillator and is configured to input the first rising edge staggering delay signal FnAdjActStaggerDly<0>. A second control terminal of the first selector Mul1 serves as a fourth input terminal of the oscillator, and is configured to input a first rising edge staggering adjustment delay inverted signal FnAdjActStagger-lyN<0>. An output terminal of the tenth delayer 410 is connected to a second input terminal of the second selector Mul2. An output terminal of the second selector Mul2 is connected to an input terminal of the eleventh delay 411. A first control terminal of the second selector Mul2 serves as a third input terminal of the oscillator and is configured to input a second rising edge staggering adjustment delay signal FnAdjActStaggerDly<1>. A second control terminal of the second selector Mul2 serves as a fourth input terminal of the oscillator and is configured to input a second rising edge staggering adjustment delay inverted signal FnAdjActStaggerDlyN<1>. An output terminal of the eleventh delay 411 is connected to an input terminal of the twelfth delay 412. An output terminal of the twelfth delay 412 is connected to an input terminal of the sixteenth NOT gate INV16.

An input terminal D of the first flip-flop DFF1 is connected to an output terminal of the seventeenth NOT gate INV17 and a terminal ClkN of the second flip-flop DFF2. The terminal Clk of the first flip-flop DFF1 is configured to input the delay signal Osc0. The terminal ClkN of the first flip-flop DFF1 is configured to input the delay inverted signal Osc0N. A terminal Q of the first flip-flop DFF1 is connected to an input terminal of the seventeenth NOT gate INV17 and a terminal Clk of the second flip-flop DFF2. A terminal D of the second flip-flop DFF2 is connected to an output terminal of the eighteenth NOT gate INV18 and a terminal ClkN of the third flip-flop DFF3. The terminal Q of the second flip-flop DFF2 is connected to an input terminal of the eighteenth NOT gate INV18, a terminal Clk of the third flip-flop DFF3, and a first input terminal of the third selector Mul3. A terminal D of the third flip-flop DFF3 is connected to an output terminal of the nineteenth NOT gate INV19. The terminal Q of the third flip-flop DFF3 is connected to an input terminal of the nineteenth NOT gate INV19 and a second input terminal of the third selector Mul3. An output terminal of the third selector Mul3 is connected to an input terminal of the first pulse conversion unit 413. An output terminal of the first pulse conversion unit 413 is connected to an input terminal of the twentieth NOT gate INV20. A first control terminal of the third selector Mul3 serves as a third input terminal of the oscillator and is configured to input a third rising edge staggering adjustment delay signal FnAdjActStaggerDly<2>. A second control terminal of the third selector Mul3 serves as a fourth input terminal of the oscillator and is configured to input a third rising edge staggering adjustment delay inverted signal FnAdjActStagger-lyN<2>. An output terminal of the twentieth NOT gate INV20 is connected to an input terminal of the twenty-first NOT gate INV21. An output terminal of the twenty-first NOT gate INV21 is connected to an input terminal of the twenty-second NOT gate INV22. An output terminal of the twenty-second NOT gate INV22 serves as an output terminal of the oscillator.

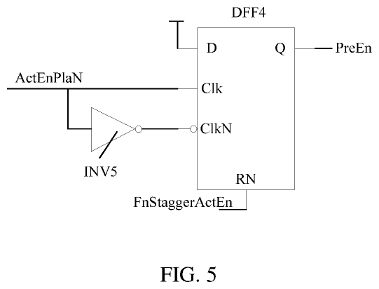

In one embodiment, as shown in FIG. 5, the staggering signal generation circuit provided by the embodiments of the disclosure may further include a fifth NOT gate INV5 and a fourth flip-flop DFF4.

An input terminal of the fifth NOT gate INV5 is connected to a clock terminal Clk of the fourth flip-flop DFF4 and is configured to input a first original signal ActEnPlaN. An output terminal of the fifth NOT gate INV5 is connected to an inverted clock terminal ClkN of the fourth flip-flop DFF4.

An input terminal D of the fourth flip-flop DFF4 is grounded. An asynchronous reset terminal RN of the fourth flip-flop DFF4 is configured to input a rising edge staggering enabling signal FnStaggerActEn. An output terminal Q of the fourth flip-flop DFF4 is configured to output falling edge enabling signal PreEn.

In a specific embodiment, the embodiments of the disclosure further include a rising edge staggering enabling signal generation circuit, a falling edge staggering enabling signal generation circuit, and a generation circuit of rising edge staggering adjustment delay signal and rising edge staggering adjustment delay inverted signal.

The rising edge staggering enabling signal circuit is configured to generate the rising edge staggering enabling signal FnStaggerActEn according to a second original signal FnCoreActAllBnk and a third original signal Burnin.

The falling edge staggering enabling signal generation circuit is configured to generate the falling edge staggering enabling signal FnStaggerPreEn according to a fourth original signal RosEnBnki and the rising edge staggering enabling signal FnStaggerActEn.

The generation circuit of rising edge staggering adjustment delay signal and rising edge staggering adjustment delay inverted signal is configured to generate the rising edge staggering adjustment delay inverted signal FnAdjActStaggerDlyN and the rising edge staggering adjustment delay signal FnAdjActStaggerDly according to a rising edge staggering delay signal ActStaggerDly.

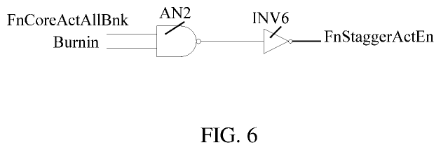

FIG. 6 is a schematic structural diagram of a rising edge staggering enabling signal generation circuit provided by the embodiments of the disclosure.

The rising edge staggering enabling signal generation circuit includes a second NAND gate AN2 and a sixth NOT gate INV6.

A first input terminal of the second NAND gate AN2 is configured to input the second original signal FnCoreActAllBnk. A second input terminal of the second NAND gate AN2 is configured to input a third original signal Burnin. An output terminal of the second NAND gate AN2 is connected to an input terminal of the sixth NOT gate INV6. An output terminal of the sixth NOT gate INV6 is configured to output the rising edge staggering enabling signal FnStagerActEn.

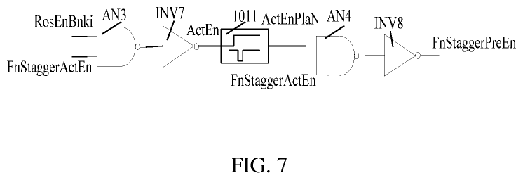

FIG. 7 is a schematic diagram of a falling edge staggering enabling signal generation circuit provided by the embodiments of the disclosure.

The falling edge staggering enabling signal generation circuit includes a third NAND gate AN3, a fourth NAND gate AN4, a seventh NOT gate INV7, an eighth NOT gate INV8, and a pulse conversion unit 1011.

A first input terminal of the third NAND gate AN3 is configured to input a fourth original signal RosEnBnki. A second input terminal of the third NAND gate AN3 is configured to input the rising edge staggering enabling signal FnStaggerActEn. An output terminal of the third NAND gate AN3 is connected to an input terminal of the seventh NOT gate INV7.

An output terminal of the seventh NOT gate INV7 is connected to an input terminal of the pulse conversion unit 1011 and is configured to output an initial signal ActEn.

An output terminal of the pulse conversion unit 1011 is connected to a first input terminal of the fourth NAND gate AN4.

A second input terminal of the fourth NAND gate AN4 is configured to input the rising edge staggering enabling signal FnStaggerActEn. An output terminal of the fourth NAND gate AN4 is connected to an input terminal of the eighth NOT gate INV8.

An output terminal of the eighth NOT gate is configured to output the falling edge staggering enabling signal FnStagePreEn.

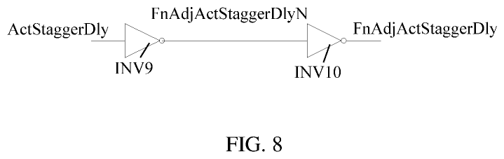

FIG. 8 is a generation circuit of rising edge staggering adjustment relay signal and rising edge staggering adjustment relay inverted signal provided by the embodiments of the disclosure.

The generation circuit of rising edge staggering adjustment relay signal and rising edge staggering adjustment relay inverted signal includes a ninth NOT gate INV9 and a tenth NOT gate INV10.

An input terminal of the ninth NOT gate INV9 is configured to input ActStaggerDly. An output terminal of the ninth NOT gate INV9 is connected to an input terminal of the tenth NOT gate INV10 and is configured to output the rising edge staggering adjustment delay inverted signal FnAdjActStaggerDlyN. An output terminal of the tenth NOT gate INV10 is configured to output the rising edge staggering adjustment delay signal FnAdjActStaggerDly.

The initial signal ActEn, rising edge clock signal ActClk, falling edge clock signal PrechgClk, first periodic pulse signal ActCkN, and second periodic pulse signal PrechgCkN are described below in combination with a waveform diagram.

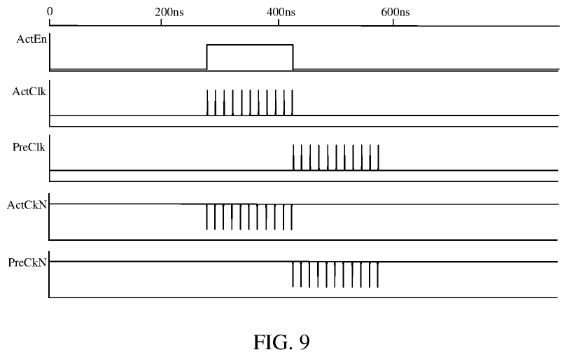

As shown in FIG. 9, the initial signal ActEn includes a rising edge and a falling edge. A first pulse of the rising edge clock signal ActClk is at the rising edge of the initial signal ActEn and then a pulse is generated at each delay time. Similarly, a first pulse of the falling edge clock signal PreClk is at the falling edge of the initial signal ActEn and then a pulse is generated at each delay time. A time interval between the first pulse and the last pulse of the rising edge clock signal ActClk is the same as that between the rising edge and the falling edge of the initial signal ActEn. A time interval between the first pulse and the last pulse of the falling edge clock signal PreClk is the same as that between the rising edge and the falling edge of the initial signal ActEn.

It can be seen from FIG. 9 that the first periodic pulse signal ActCkN is an inverted signal of the rising edge clock signal ActClk, and the second periodic pulse signal is an inverted signal of the falling edge clock signal PreClk.

In the above-mentioned embodiments, the first periodic pulse signals and the second periodic pulse signals are generated according to the initial signal, and then the first periodic pulse signals and the second periodic pulse signals are counted. How to count the first periodic pulse signals and the second periodic pulse signals will be described below.

The counting circuit provided by the embodiments of the disclosure includes a plurality of rising edge triggering signal generation circuits and a plurality of falling edge triggering signal generation circuits that may be connected in series.

The number of the rising edge triggering signal generation circuits is the same as that of the falling edge triggering signal generation circuits.

Each rising edge triggering signal generation circuit is configured to generate rising edge triggering signal CntActN according to the first periodic pulse signal ActCkN, rising edge staggering enabling delay signal FnStaggerActEnDly, rising edge staggering enabling signal FnStaggerActEn, a power supply voltage, and rising edge counting signal CntAct that is output by a last rising edge triggering signal generation circuit connected to the rising edge triggering signal generation circuit.

Each falling edge trigger signal generation circuit is configured to generate falling edge triggering signal CntPreN according to the second periodic pulse signal PrechgCkN, falling edge staggering pulse delay signal fnStaggerPrechgEnDly, falling edge staggering enabling signal fnStaggerPrechgEn, a power supply voltage, and falling edge counting signal CntPre that is output by a last falling edge trigger signal generation circuit connected in series with the falling edge triggering signal generation circuit.

The rising edge triggering signal generation circuit and the falling edge triggering signal generation circuit are described in detail below.

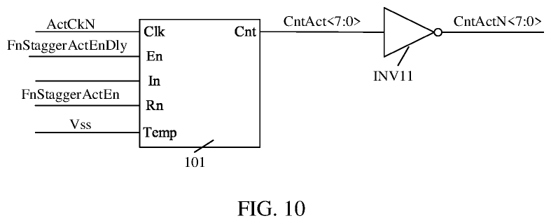

FIG. 10 is a schematic structural diagram of a rising edge triggering signal generation circuit provided by the embodiments of the disclosure.

The rising edge triggering signal generation circuit may include a first counter 101 and an eleventh NOT gate INV11.

A first input terminal of the first counter 101 is configured to input the first periodic pulse signal ActCkN. A second input terminal of the first counter 101 is configured to input the rising edge staggering enabling delay signal FnStaggerActEnDly. A third input terminal of the first counter 101 is configured to input a power supply voltage VSS or the rising edge counting signal CntAct output by a last first counter 101 connected to the first counter 101. A fourth input terminal of the first counter 101 is configured to input the rising edge staggering enable signal FnStaggerActEn. A fifth input terminal of the first counter 101 is configured to input the power supply voltage VSS. An output terminal of the first counter 101 is connected to a third input terminal of the next first counter 101 and an input terminal of the eleventh NOT gate INV11, and is configured to output the rising edge counting signal CntAct.

An output terminal of the eleventh NOT gate INV11 is configured to output a rising edge triggering signal CntActN.

It is to be noted that CntAct<7:0> in FIG. 10 represents eight CntActs, i.e., CntAct<0>, CntAct<1>, CntAct<2>, CntAct<3>, CntAct<4>, CntAct<5>, CntAct<6>, and CntAct <7>. That is, there are eight rising edge clock counting circuits. A third input terminal of a first counter in the first rising edge counting circuit, i.e., terminal In, inputs the power supply voltage VSS. An output terminal of the first counter in the second rising edge counting circuit is connected to the third input terminal of the first counter in a first rising edge triggering signal generation circuit, and so on.

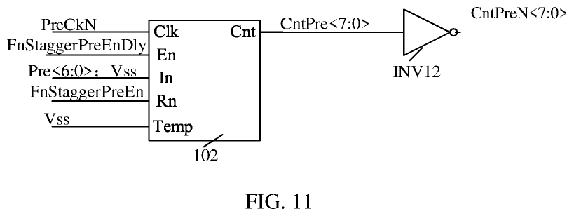

FIG. 11 is a schematic structural diagram of a falling edge triggering signal generation circuit provided by the embodiments of the disclosure.

The falling edge triggering signal generation circuit may include a second counter 102 and a twelfth NOT gate INV12.

A first input terminal of the second counter 102 is configured to input the second periodic pulse signal PreCkN. A second input terminal of the second counter 102 is configured to input the falling edge staggering enabling delay signal FnStaggerPreEnDly. A third input terminal of the second counter 102 is configured to input the power supply voltage VSS or falling edge counting signal CntPre output by a last second counter 102 connected to the second counter 102. A fourth input terminal of the second counter 102 is configured to input the falling edge staggering enabling signal FnStaggerPreEn. A fifth input terminal of the second counter 102 is configured to input the power supply voltage VSS. An output terminal of the second counter 102 is connected to an input terminal of the twelfth NOT gate INV12 and is configured to output the falling edge counting signal CntPre.

An output terminal of the twelfth NOT gate INV12 is configured to output the falling edge triggering signal CntPreN.

It is to be noted that CntPre<7:0> in FIG. 11 represents eight CntPres, i.e., CntPre<0>, CntPre<1>, CntPre<2>, CntPre<3>, CntPre<4>, CntPre<5>, CntPre<6>, and CntPre <7>. That is, there are eight falling edge triggering signal generation circuits. A third input terminal of a second counter in the first falling edge triggering signal generation circuit, i.e., terminal In, inputs the power supply voltage VSS. An output terminal of the second counter in the second falling edge triggering signal generation circuit is connected to the third input terminal of the second counter in the first falling edge triggering signal generation circuit, and so on.

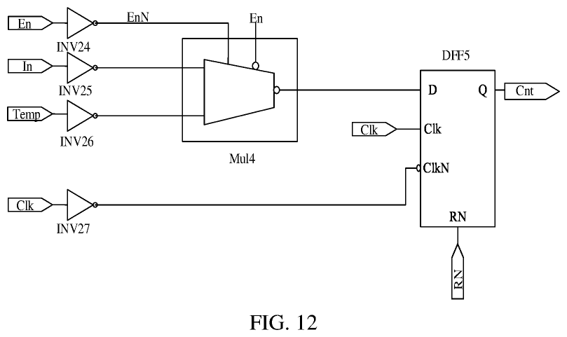

In some specific embodiments, the first counter 101 and the second counter 102 may be the same counter, as shown in FIG. 12, which may include a twenty-fourth NOT gate INV24, a twenty-fifth NOT gate INV25, a twenty-sixth NOT gate INV26, a twenty-seventh NOT gate INV27, a fifth flip-flop DFF5, and a fourth selector Mul4.

An input terminal of the twenty-fourth NOT gate and a second control terminal of the fourth selector Mul 4 serve as a terminal En of the counter, and an output terminal of the twenty-fourth NOT gate INV24 is connected to a first control terminal of the fourth selector Mul4. An input terminal of the twenty-fifth NOT gate INV25 serves as a terminal In of the counter, and an output terminal of the twenty-fifth NOT gate INV25 is connected to a first input terminal of the fourth selector Mul4. An input terminal of the twenty-sixth NOT gate INV26 serves as a terminal Temp of the counter, and an output terminal of the twenty-sixth NOT gate INV26 is connected to a second input terminal of the fourth selector Mul4. An input terminal of the twenty-seventh NOT gate INV27 and a terminal Clk of the fifth flip-flop DFF5 serve as a terminal Clk of the counter. An output terminal of the twenty-seventh NOT gate INV27 is connected to a terminal ClkN of the fifth flip-flop DFF5. A terminal RN of the fifth flip-flop DFF5 serves as a terminal RN of the counter. A terminal Q of the fifth flip-flop DFF5 serves as a terminal Cnt of the counter.

In above-mentioned embodiments, the counting circuit counts the first periodic pulse signals and the second periodic pulse signals to generate the rising edge triggering signal and the falling edge triggering signal. The signal generation circuit generates a staggering pulse signal according to the input rising edge triggering signal and the input falling edge triggering signal.

The staggering pulse signal generation circuit provided by the embodiments of the disclosure may further include a rising edge staggering enabling delay signal generation circuit and a falling edge staggering enabling delay signal generation circuit.

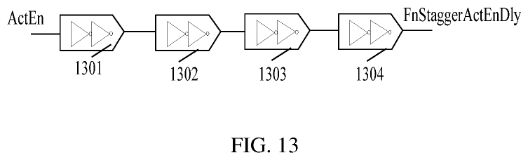

As shown in FIG. 13, the rising edge staggering enabling delay signal generation circuit may include a first delayer 1301, a second delayer 1302, a third delayer 1303, and a fourth delayer 1304.

An input terminal of the first delayer 1301 is configured to input an initial signal ActEn. An output terminal of the first delayer 1301 is connected to an input terminal of the second delayer 1302. An output terminal of the second delayer 1302 is connected to an input terminal of the third delayer 1303. An output terminal of the third delayer 1303 is connected with an input terminal of the fourth delayer 1304. An output terminal of the fourth delayer 1304 is configured to output a rising edge staggering enabling delay signal FnStaggerActEnDly.

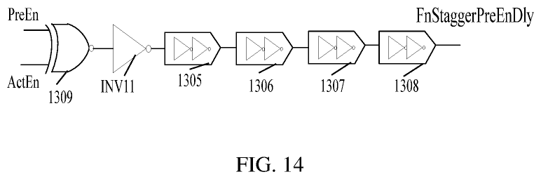

As shown in FIG. 14, the falling edge staggering enabling delay signal generation circuit may include a fifth delayer 1305, a sixth delayer 1306, a seventh delayer 1307, an eighth delayer 1308, a NOR gate 1309, and a thirteenth NOT gate INV13.

A first input terminal of the NOR gate 1309 is configured to input an initial signal ActEn. A second input terminal of the NOR gate 1309 is configured to input a falling edge enabling signal PreEn. An output terminal of the NOR gate 1309 is connected to an input terminal of the thirteenth NOT gate INV13. An output terminal of the thirteenth NOT gate INV13 is connected to an input terminal of the fifth delayer 1305. An output terminal of the fifth delayer 1305 is connected to an input terminal of the sixth delayer 1306. An output terminal of the sixth delayer 1306 is connected to an input terminal of the seventh delayer 1307. An output terminal of the seventh delayer 1307 is connected to an input terminal of the eighth delayer 1308. An output terminal of the eighth delayer 1308 is configured to output a falling edge staggering enabling delay signal FnStaggerPreEnDly.

The signal generation circuit will be described in detail below.

The signal generation circuit provided by the embodiments of the disclosure may include a plurality of signal generation sub-circuits. Each signal generation sub-circuit is configured to generate a staggering pulse sub-signal according to an input rising edge triggering signal and an input falling edge triggering signal. A plurality of staggering pulse sub-signals forms the staggering pulse signal.

In specific implementations, if the intervals of the rising edge trigger signals input into adjacent signal generation sub-circuits in the plurality of signal generation sub-circuits are the same, then the generated staggering pulse signal is a staggering pulse signal with equal interval.

If the intervals of the rising edge triggering signals input into the adjacent signal generation sub-circuits of the plurality of signal generation sub-circuits are different, the generated staggering pulse signal is a staggering pulse signal with unequal interval.

If the clock periods of the rising edge triggering signals and the falling edge triggering signals input into each signal generation sub-circuit are the same, then the generated staggering pulse signal is a staggering pulse signal with equal pulse width.

If the clock periods of the rising edge triggering signals and the falling edge triggering signals input into each signal generation sub-circuit are different, then the generated staggering pulse signal is a staggering pulse signal with unequal pulse width.

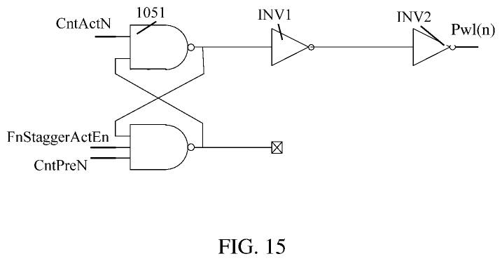

FIG. 15 is a schematic structural diagram of a signal generation sub-circuit provided by the embodiments of the disclosure.

The signal generation sub-circuit may include an SR latch 1051, a first NOT gate INV1, and a second NOT gate INV2.

A first input terminal of the SR latch 1051 is configured to input a rising edge triggering signal CntActN. A second input terminal of the SR latch 1051 is configured to input a falling edge triggering signal CntPreN. A third input terminal of the SR latch 1051 is configured to input a rising edge staggering enabling signal FnStaggerActEn. An output terminal of the SR latch 1051 is connected to an input terminal of the first NOT gate INV1. An output terminal of the first NOT gate INV1 is connected to an input terminal of the second NOT gate INV2. An output terminal of the second NOT gate INV2 outputs a staggering pulse sub-signal Pwl(n).

For ease of understanding, the following will describe the staggering pulse signals respectively as equal interval and equal pulse, equal interval and unequal pulse, unequal interval and equal pulse, and unequal interval and unequal pulse.

### Embodiment 1

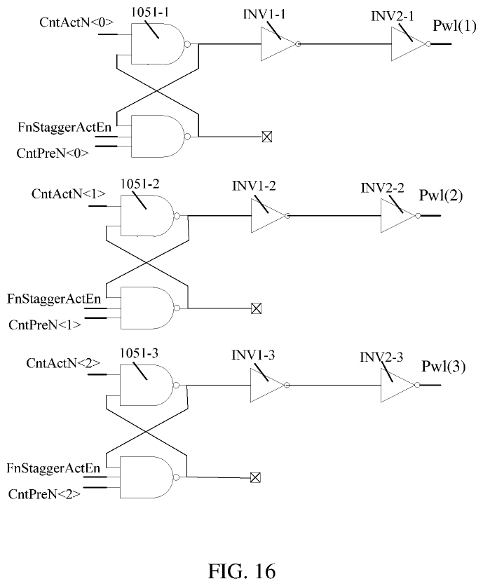

As shown in FIG. 16, the rising edge triggering signal input into the first signal generation sub-circuit is CntActN<0>, and the falling edge triggering signal is CntPreN<0>. The rising edge triggering signal input into the second signal generation sub-circuit is CntActN<1>, and the falling edge triggering signal is CntPreN<1>. The rising edge triggering signal input into the third signal generation sub-circuit is CntActN<2>, and the falling edge triggering signal is CntPreN<2>.

The time interval between CntActN<0> and CntActN<1> is one period of the first periodic pulse signal, and the time interval between CntActN<1> and CntActN<2> is one period of the first periodic pulse signal. Therefore, the generated staggering pulse signal is a staggering pulse signal with equal interval.

The time interval between CntActN<0> and CntPreN<0> is one period of an initial signal ActEn, the time interval between CntActN<1> and CntPreN<1> is one period of the initial signal ActEn, and the time interval between CntActN<2> and CntPreN<2> is one period of initial signal ActEn. Therefore, the generated staggering pulse signal is a staggering pulse signal with equal pulse.

It is to be noted that the circuit that outputs a staggering sub-signal Pwl (1) and the circuit that outputs a staggering sub-signal Pwl (2) are adjacent signal generation sub-circuits. The circuit that outputs the staggering sub-signal Pwl (2) and the circuit that outputs staggering sub-signal Pwl (3) are adjacent signal generation sub-circuits. CntActN<0> and CntActN<1> are rising edge triggering signals input into adjacent signal generation sub-circuits. CntActN<1> and CntActN<2> are also rising edge triggering signals input into adjacent signal generation sub-circuits. CntActN<0> and CntPreN<0> are a rising edge triggering signal and its corresponding falling edge triggering signal input into the same signal generation sub-circuit. CntActN<1> and CntPreN<1> are a rising edge triggering signal and its corresponding falling edge triggering signal input into the same signal generation sub-circuit. CntActN<2> and CntPreN<2> are a rising edge triggering signal and its corresponding falling edge triggering signal input into the same signal generation sub-circuit.

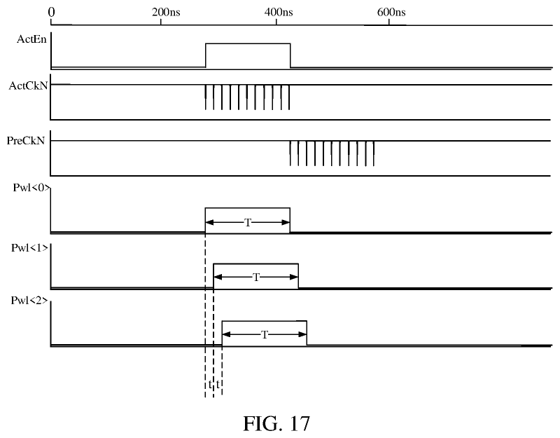

FIG. 17 is a waveform diagram of a signal generated on the basis of FIG. 16.

Assuming that the clock period of the first periodic pulse signal is t and the period of the initial signal is T, the interval between staggering pulse signals is t and the pulse width is T. It may also be seen from FIG. 17 that the staggering pulse signal is a staggering pulse signal with equal interval and equal pulse.

### Embodiment 2

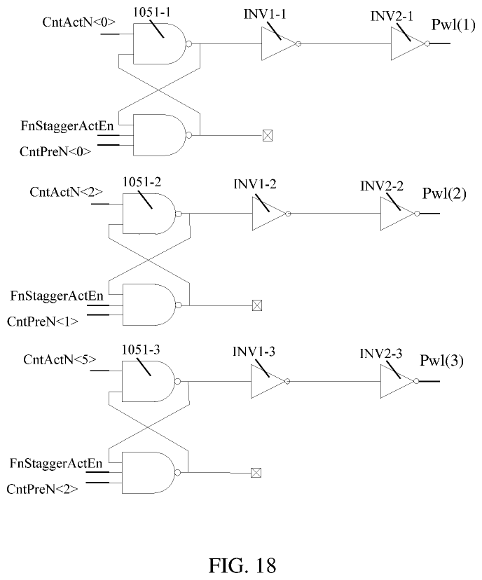

As shown in FIG. 18, the rising edge triggering signal input into the first signal generation sub-circuit is CntActN<0>, and the falling edge triggering signal is CntPreN<0>. The rising edge triggering signal input into the second signal generation sub-circuit is CntActN<2>, and the falling edge triggering signal is CntPreN<1>. The rising edge triggering signal input into the third signal generation sub-circuit is CntActN<5>, and the falling edge triggering signal is CntPreN<2>.

The time interval between CntActN<0> and CntActN<2> is two periods of the first periodic pulse signals, and the time interval between CntActN<2> and CntActN<5> is three periods of the first periodic pulse signals. Therefore, the generated staggering pulse signal is a staggering pulse signal with unequal interval.

The time interval between CntActN<0> and CntPreN<0> is one period of the initial signal ActEn, the time interval between CntActN<2> and CntPreN<1> is one period of the initial signal ActEn minus the clock period of one falling edge inverted signal, and the time interval between CntActN<5> and CntPreN<2> is one period of initial signal ActEn minus the clock period of three falling edge inverted signals, so that the generated staggering pulse signal is a staggering pulse signal with unequal pulse.

It is to be noted that the circuit that outputs a staggering sub-signal Pwl (1) and the circuit that outputs a staggering sub-signal Pwl (2) are adjacent signal generation sub-circuits. The circuit that outputs the staggering sub-signal Pwl (2) and the circuit that outputs staggering sub-signal Pwl (3) are adjacent signal generation sub-circuits. CntActN<0> and CntActN<2> are rising edge triggering signals input into adjacent signal generation sub-circuits. CntActN<2> and CntActN<5> are also rising edge triggering signals input into adjacent signal generation sub-circuits. CntActN<0> and CntPreN<0> are a rising edge triggering signal and its corresponding falling edge triggering signal input into the same signal generation sub-circuit. CntActN<2> and CntPreN<1> are a rising edge triggering signal and its corresponding falling edge triggering signal input into the same signal generation sub-circuit. CntActN<5> and CntPreN<2> are a rising edge triggering signal and its corresponding falling edge triggering signal input into the same signal generation sub-circuit.

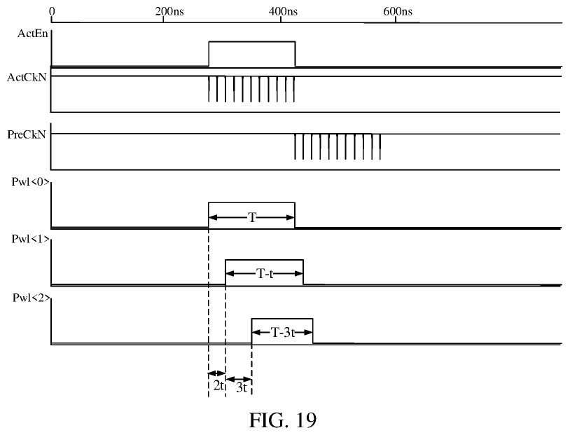

FIG. 19 is a waveform diagram of a signal generated on the basis of FIG. 18.

Assuming that the clock period of the first periodic pulse signal is t, the clock period of the falling edge inverted signal is also t, and the period of the initial signal is T, then it may also be seen from FIG. 17 that the staggering pulse signal is a staggering pulse signal with unequal interval and unequal pulse.

### Embodiment 3

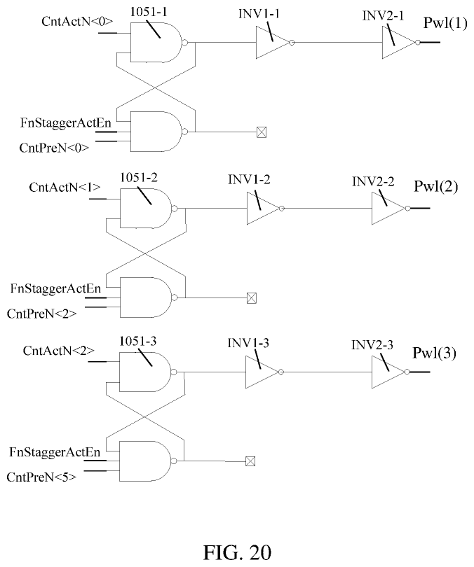

As shown in FIG. 20, the rising edge triggering signal input into the first signal generation sub-circuit is CntActN<0>, and the falling edge triggering signal is CntPreN<0>. The rising edge triggering signal input into the second signal generation sub-circuit is CntActN<1>, and the falling edge triggering signal is CntPreN<2>. The rising edge triggering signal input into the third signal generation sub-circuit is CntActN<2>, and the falling edge triggering signal is CntPreN<5>.

The time interval between CntActN<0> and CntActN<1> is one period of the first periodic pulse signals, and the time interval between CntActN<1> and CntActN<2> is one period of the first periodic pulse signals. Therefore, the generated staggering pulse signal is a staggering pulse signal with equal interval.

The time interval between CntActN<0> and CntPreN<0> is one period of the initial signal ActEn, the time interval between CntActN<1> and CntPreN<2> is one period of the initial signal ActEn plus the clock cycle of one falling edge inverted signal, and the time interval between CntActN<5> and CntPreN <2> is one period of the initial signal ActEn plus the clock period of three falling edge inverted signals. Therefore, the generated staggering pulse signal is a staggering pulse signal with unequal pulse.

It is to be noted that the circuit that outputs a staggering sub-signal Pwl (1) and the circuit that outputs a staggering sub-signal Pwl (2) are adjacent signal generation sub-circuits. The circuit that outputs the staggering sub-signal Pwl (2) and the circuit that outputs staggering sub-signal Pwl (3) are adjacent signal generation sub-circuits. CntActN<0> and CntActN<1> are rising edge triggering signals input into adjacent signal generation sub-circuits. CntActN<1> and CntActN<2> are also rising edge triggering signals input into adjacent signal generation sub-circuits. CntActN<0> and CntPreN<0> are a rising edge triggering signal and its corresponding falling edge triggering signal input into the same signal generation sub-circuit. CntActN<1> and CntPreN<2> are a rising edge triggering signal and its corresponding falling edge triggering signal input into the same signal generation sub-circuit. CntActN<5> and CntPreN<2> are a rising edge triggering signal and its corresponding falling edge triggering signal input into the same signal generation sub-circuit.

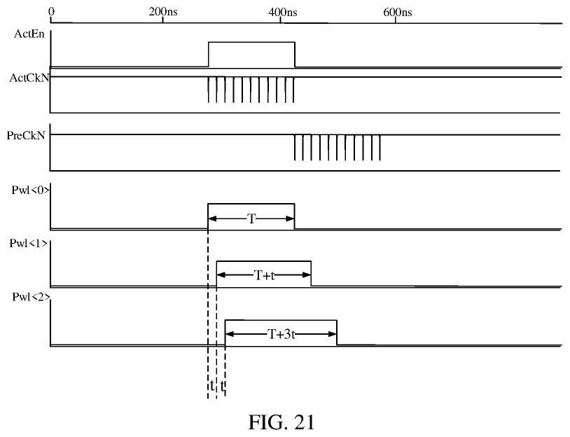

FIG. 21 is a waveform diagram of a signal generated on the basis of FIG. 20.

Assuming that the clock period of the first periodic pulse signal is t, the clock period of the falling edge inverted signal is also t, and the period of the initial signal is T, then it may also be seen from FIG. 21 that the staggering pulse signal is a staggering pulse signal with equal interval and unequal pulse.

### Embodiment 4

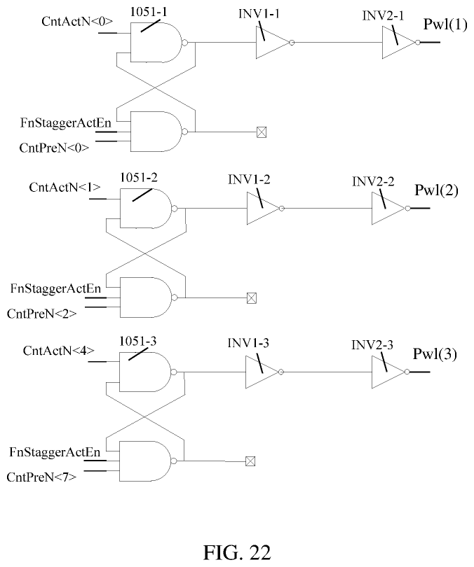

As shown in FIG. 22, the rising edge triggering signal input into the first signal generation sub-circuit is CntActN<0>, and the falling edge triggering signal is CntPreN<0>. The rising edge triggering signal input into the second signal generation sub-circuit is CntActN<1>, and the falling edge triggering signal is CntPreN<1>. The rising edge triggering signal input into the third signal generation sub-circuit is CntActN<4>, and the falling edge triggering signal is CntPreN<4>.

The time interval between CntActN<0> and CntActN<1> is one period of the first periodic pulse signals, the time interval between CntActN<1> and CntActN<4> is three periods of the first periodic pulse signals. Therefore, the generated staggering pulse signal is a staggering pulse signal with unequal interval.

The time interval between CntActN<0> and CntPreN<0> is one period of initial signal ActEn, the time interval between CntActN<1> and CntPreN<1> is one period of the initial signal ActEn, and the time interval between CntActN<4> and CntPreN<4> is one period of initial signal ActEn. Therefore, the generated staggering pulse signal is a staggering pulse signal with equal pulse.

It is to be noted that the circuit that outputs a staggering sub-signal Pwl (1) and the circuit that outputs a staggering sub-signal Pwl (2) are adjacent signal generation sub-circuits. The circuit that outputs the staggering sub-signal Pwl (2) and the circuit that outputs staggering sub-signal Pwl (3) are adjacent signal generation sub-circuits. CntActN<0> and CntActN<1> are rising edge triggering signals input into adjacent signal generation sub-circuits. CntActN<1> and CntActN<4> are also rising edge triggering signals input into adjacent signal generation sub-circuits. CntActN<0> and CntPreN<0> are a rising edge triggering signal and its corresponding falling edge triggering signal input into the same signal generation sub-circuit. CntActN<1> and CntPreN<1> are a rising edge triggering signal and its corresponding falling edge triggering signal input into the same signal generation sub-circuit. CntActN<4> and CntPreN<4> are a rising edge triggering signal and its corresponding falling edge triggering signal input into the same signal generation sub-circuit.

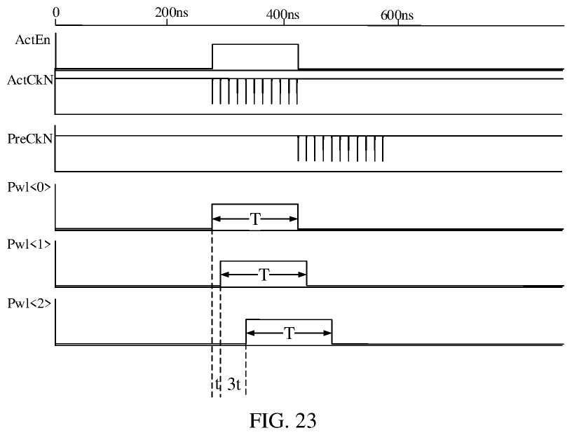

FIG. 23 is a waveform diagram of a signal generated on the basis of FIG. 22.

Assuming that the clock period of the first periodic pulse signal is t, the clock period of the falling edge inverted signal is also t, and the period of the initial signal is T, then it may also be seen from FIG. 23 that the staggering pulse signal is a staggering pulse signal with unequal interval and equal pulse.

According to the staggering pulse signal generation circuit provided by the embodiments of the disclosure, the counting circuit counts the first periodic pulse signals and the second periodic pulse signals to generate the rising edge triggering signal and the falling edge triggering signal, and the signal generation circuit generates the staggering pulse signal according to the input rising edge triggering signal and the input falling edge triggering signal. The intervals between the rising edge triggering signals input into each signal generation circuit may be the same or different, and the intervals between the rising edge triggering signal and the falling edge triggering signal input into each signal generation circuit may also be the same or different, and thus the pulse width and the interval of the obtained staggering pulse signals may be set flexibly, thereby improving the flexibility of the staggering pulse signal generation circuit.

Based on the same inventive concept, the embodiments of the disclosure further provide an integrated chip. The integrated chip includes any one of the staggering signal generation circuits as described above.

For specific implementations of the integrated chip, reference may be made to the implementations of the staggering signal generation circuit, which is not described in detail herein.

Various embodiments of the present disclosure can have one or more of the following advantages.

In the embodiments of the disclosure, the counting circuit counts the first periodic pulse signals and the second periodic pulse signals to generate the rising edge triggering signals and the falling edge triggering signals, and the signal generation circuit generates the staggering pulse signal according to the input rising edge triggering signals and the input falling edge triggering signals. The intervals between the rising edge triggering signals input into each signal generation circuit may be the same or different, and the intervals between the rising edge triggering signal and the falling edge triggering signal input into each signal generation circuit may also be the same or different, and thus the pulse width and the interval of the obtained staggering pulse signals may be set flexibly, thereby improving the flexibility of the staggering pulse signal generation circuit.

It is apparent that those skilled in the art can make various modifications and variations to the disclosure without departing from the spirit and scope of the embodiments of the disclosure. Thus, if such modifications and variations of the embodiments of the disclosure fall within the scope of the appended claims and their equivalents, the disclosure is also intended to cover the modifications and variations.

What is claimed is:

1. A staggering signal generation circuit, comprising:
a pulse generation circuit, configured to generate a first periodic pulse signal and a second periodic pulse signal according to an initial signal;
a counting circuit, configured to count the first periodic pulse signal and the second periodic pulse signal to generate a plurality of rising edge triggering signals and falling edge triggering signals; and
a signal generation circuit, configured to generate a staggering pulse signal according to input rising edge triggering signals and input falling edge triggering signals.

2. The circuit of claim 1, wherein the signal generation circuit comprises a plurality of signal generation sub-circuits;
wherein each signal generation sub-circuit is configured to generate a staggering pulse sub-signal according to the input rising edge triggering signals and the input falling edge triggering signals; and
wherein a plurality of the staggering pulse sub-signals form the staggering pulse signal.

3. The circuit of claim 2, wherein the signal generation sub-circuit comprises a Set-Reset (SR) latch, a first NOT gate, and a second NOT gate;
wherein a first input terminal of the SR latch is configured to input the rising edge triggering signal, a second input terminal of the SR latch is configured to input the falling edge triggering signal, a third input terminal of the SR latch is configured to input a rising edge staggering enabling signal, and an output terminal of the SR latch is connected to an input terminal of the first NOT gate;
an output terminal of the first NOT gate is connected to an input terminal of the second NOT gate; and
an output terminal of the second NOT gate is configured to output the staggering pulse sub-signal.

4. The circuit of claim 2, wherein if intervals of rising edge triggers signals input into adjacent signal generation sub-circuits of the plurality of signal generation sub-circuits are the same, the staggering pulse signal is a staggering pulse signal with equal interval;
if the intervals of the rising edge trigger signals input into the adjacent signal generation sub-circuits of the plurality of signal generation sub-circuits are different, the staggering pulse signal is a staggering pulse signal with unequal interval;
if the intervals of the rising edge trigger signals and the corresponding falling edge counting signals input into each of the signal generation sub-circuits are the same, the staggering pulse signal is a staggering pulse signal with equal pulse width; and
if the intervals of the rising edge trigger signals and the corresponding falling edge counting signals input into each of the signal generation sub-circuits are different, the staggering pulse signal is a staggering pulse signal with unequal pulse width.

5. The circuit of claim 1, wherein the pulse generation circuit comprises a first periodic pulse signal generation circuit and a second periodic pulse signal generation circuit;
wherein the first periodic pulse signal generation circuit is configured to generate a first periodic pulse signal according to the initial signal and a first control signal; and
the second periodic pulse signal generation circuit is configured to generate a second periodic pulse signal according to the initial signal and a second control signal.

6. The circuit of claim 5, wherein the first periodic pulse signal generation circuit comprises a first oscillator and a third NOT gate, and the first control signal comprises a rising edge staggering enabling signal, a rising edge staggering adjustment delay signal, and a rising edge staggering adjustment delay inverted signal;
wherein a first input terminal of the first oscillator is configured to input the initial signal, a second input terminal of the first oscillator is configured to input the rising edge staggering enabling signal, a third input terminal of the first oscillator is configured to input the rising edge staggering adjustment delay signal, a fourth input terminal of the first oscillator is configured to input the rising edge staggering adjustment delay inverted signal, an output terminal of the first oscillator is connected with an input terminal of the third NOT gate and is configured to output a rising edge clock signal; and an output terminal of the third NOT gate is configured to output the first periodic pulse signal;
wherein the second periodic pulse signal generation circuit comprises a second oscillator, a fourth NOT gate, and a first NAND gate, and the second control signal comprises a falling edge staggering enabling signal, a rising edge staggering adjustment delay signal, a rising edge staggering adjustment delay inverted signal, and a falling edge enabling signal;
wherein an input terminal of the fourth NOT gate is configured to input the initial signal, and an output terminal of the fourth NOT gate is connected to a first input terminal of the second oscillator;
a second input terminal of the second oscillator is configured to input the falling edge staggering enabling signal, a third input terminal of the second oscillator is configured to input the rising edge staggering adjustment delay signal, a fourth input terminal of the second oscillator is configured to input the rising edge staggering adjustment delay signal, and an output terminal of the second oscillator is connected to a first input terminal of the first NAND gate; and
a second input terminal of the first NAND gate is configured to input the falling edge enabling signal, and an output terminal of the first NAND gate is configured to output the second periodic pulse signal.

7. The circuit of claim 6, further comprising: a fifth NOT gate and a flip-flop, wherein
an input terminal of the fifth NOT gate is connected to a clock terminal of the flip-flop and is configured to input a first original signal, and an output terminal of the fifth NOT gate is connected to an inverted clock terminal of the flip-flop; and
an input terminal of the flip-flop is grounded, an asynchronous reset terminal of the flip-flop is configured to input the rising edge staggering enabling signal, and an output terminal of the flip-flop is configured to output the falling edge enabling signal.

8. The circuit of claim 5, further comprising: a second NAND gate, a third NAND gate, a fourth NAND gate, a sixth NOT gate, a seventh NOT gate, an eighth NOT gate, a ninth NOT gate, a tenth NOT gate, and a pulse conversion unit, wherein
a first input terminal of the second NAND gate is configured to input a second original signal, a second input terminal of the second NAND gate is configured to input a third original signal, and an output terminal of the second NAND gate is connected to an input terminal of the sixth NOT gate;
an output terminal of the sixth NOT gate is configured to output a rising edge staggering enabling signal;
a first input terminal of the third NAND gate is configured to input a fourth original signal, a second input terminal of the third NAND gate is configured to input the rising edge staggering enabling signal, an output terminal of the third NAND gate is connected to an input terminal of the seventh NAND gate;
an output terminal of the seventh NOT gate is connected to an input terminal of the pulse conversion unit and is configured to output the initial signal;
an output terminal of the pulse conversion unit is connected to a first input terminal of the fourth NAND gate;
a second input terminal of the fourth NAND gate is configured to input the rising edge staggering enabling signal, and an output terminal of the fourth NAND gate is connected to an input terminal of the eighth NAND gate;
an output terminal of the eighth NOT gate is configured to output the falling edge staggering enabling signal;
an input terminal of the ninth NOT gate is configured to input a rising edge staggering delay signal, an output terminal of the ninth NOT gate is connected to an input terminal of a tenth NOT gate and is configured to output a rising edge staggering adjustment delay inverted signal; and
an output terminal of the tenth NOT gate is configured to output a rising edge staggering adjustment delay signal.

9. The circuit of claim 1, wherein the counting circuit comprises a plurality of rising edge triggering signal generation circuits connected in series and a plurality of falling edge triggering signal generation circuits connected in series;
wherein each rising edge triggering signal generation circuit is configured to generate the rising edge triggering signal according to the first periodic pulse signal, a rising edge staggering enabling delay signal, a rising edge staggering enabling signal, a power supply voltage, and a rising edge counting signal output by a last rising edge counting signal generation circuit connected to the rising edge triggering signal generation circuit; and
each falling edge triggering signal generation circuit is configured to generate the falling edge triggering signal according to the second periodic pulse signal, a falling edge staggering enabling delay signal, a falling edge staggering enabling signal, a power supply voltage, and a falling edge counting signal output by a last falling edge counting signal generation circuit connected to the falling edge triggering signal generation circuit.

10. The circuit of claim 9, wherein the rising edge triggering signal generation circuit comprises a first counter and an eleventh NOT gate, wherein
a first input terminal of the first counter is configured to input the first periodic pulse signal, a second input terminal of the first counter is configured to input the rising edge staggering enabling delay signal, a third input terminal of the first counter is configured to input the power supply voltage or a rising edge counting signal output by a last first counter connected to the first counter, a fourth input terminal of the first counter is configured to input the rising edge staggering enabling signal, a fifth input terminal of the first counter is configured to input the power supply voltage, and an output terminal of the first counter is connected to a third input terminal of a next first counter and an input terminal of the eleventh NOT gate and is configured to output a rising edge counting signal;
an output terminal of the eleventh NOT gate is configured to output the rising edge triggering signal;
the falling edge triggering signal generation circuit comprises a second counter and a twelfth NOT gate;
wherein a first input terminal of the second counter is configured to input the second periodic pulse signal, a second input terminal of the second counter is configured to input the falling edge staggering enabling delay signal, a third input terminal of the second counter is configured to input the power supply voltage or a falling edge counting signal output by a last second counter connected to the second counter, a fourth input terminal of the second counter is configured to input a falling edge staggering enabling signal, a fifth input terminal of the second counter is configured to input a power supply voltage, and an output terminal of the second counter is connected to an input terminal of the twelfth NOT gate and is configured to output a falling edge triggering signal; and
an output terminal of the twelfth NOT gate is configured to output the falling edge triggering signal.

11. The circuit of claim 10, further comprising: a first delayer, a second delayer, a third delayer, a fourth delayer, a fifth delayer, a sixth delayer, a seventh delayer, an eighth delayer, an NOR gate, and a thirteenth NOT gate, wherein
an input terminal of the first delayer is configured to input the initial signal, an output terminal of the first delayer is connected to an input terminal of the second delayer, an output terminal of the second delayer is connected to an input terminal of the third delayer, an output terminal of the third delayer is connected to an input terminal of the fourth delayer, an output terminal of the fourth delayer is configured to output the rising edge staggering enabling delay signal;
a first input terminal of the NOR gate is configured to input the initial signal, a second input terminal of the NOR gate is configured to input a falling edge enabling signal, an output terminal of the NOR gate is connected to an input terminal of the thirteenth NOT gate, an output terminal of the thirteenth NOT gate is connected to an input terminal of the fifth delayer, an output terminal of the fifth delayer is connected to an input terminal of the sixth delayer, an output terminal of the sixth delayer is connected to an input terminal of the seventh delayer, an output terminal of the seventh delayer is connected to an input terminal of the eighth delayer, and an output terminal of the eighth delayer is configured to output the falling edge staggering enabling delay signal.

12. An integrated chip, comprising a staggering signal generation circuit,
wherein the staggering signal generation circuit, comprising:
a pulse generation circuit, configured to generate a first periodic pulse signal and a second periodic pulse signal according to an initial signal;
a counting circuit, configured to count the first periodic pulse signal and the second periodic pulse signal to generate a plurality of rising edge triggering signals with equal interval and falling edge triggering signals; and
a signal generation circuit, configured to generate a staggering pulse signal according to input rising edge triggering signals and input falling edge triggering signals.
